(19) United States
(12) Patent Application Publication
(10) Pub. No.: US 2026/0239999 A1
(43) Pub. Date: Aug. 13, 2026

(54) ELECTRONIC COMPONENT AND METHOD FOR MOUNTING AN ELECTRONIC COMPONENT

(71) Applicant: ams-OSRAM International GmbH, Regensburg (DE)

(72) Inventor: Michael Müller, Pfaffenhofen (DE)

(21) Appl. No.: 19/155,844

(22) PCT Filed: Feb. 23, 2024
(86) PCT No.: PCT/EP2024/054653

§ 371 Date: Aug. 12, 2025

(30) Foreign Application Priority Data
Feb. 23, 2023 (DE) 10 2023 104 437.0

(51) Int. Cl. H10W 70/40

(52) U.S. Cl. CPC H10W 70/417

(57) ABSTRACT

In an embodiment an electronic component includes a housing with a moldable material, a leadframe embedded in the moldable material, and an electronic semiconductor chip, wherein the housing has a mounting surface and outer walls, wherein the leadframe has a top side and a bottom side situated opposite the top side, wherein the leadframe has at least two separate leadframe portions, wherein the leadframe portions form chip contact pads on the top side, wherein the leadframe has solder contact structures connected to the leadframe portions, and wherein the solder contact structures are arranged in regions of housing corners formed at the mounting surface, and are accessible at the mounting surface and/or the outer walls.

### CROSS-REFERENCE TO RELATED APPLICATIONS

This patent application is a national phase filing under section 371 of PCT/EP2024/054653, filed Feb. 23, 2024, which claims the priority of German patent application no. 10 2023 104 437.0, filed Feb. 23, 2023, each of which is incorporated herein by reference in its entirety.

### TECHNICAL FIELD

The invention relates to an electronic component and to a method for mounting an electronic component.

### BACKGROUND

The suitability of electronic components for soldering, the stability of the soldered joint, e.g. in respect of corrosion, and the robustness thereof present ongoing challenges in the design of new structures.

Electronic components with wetting flanks or solder contact surfaces are known from the prior art. Such structures require valuable space in an electronic component and must be integrated into the electronic component while being insulated as well as possible, and this can be achieved only with difficulty in the case of small structures and generally entails disadvantages in terms of robustness. Insulated wetting flanks or solder contact surfaces are necessary inasmuch as penetration by a flux or even a solder material via the solder contact surfaces into the electronic component or into active regions of the electronic component should be avoided.

### SUMMARY

Embodiments provide an improved electronic component and specify an improved method for mounting an electronic component.

An electronic component has a housing comprising a moldable material and has a leadframe embedded in the moldable material. The housing has a mounting surface and outer walls, and the leadframe has a top side and a bottom side situated opposite the top side. The leadframe has at least two separate leadframe portions, and the leadframe portions form chip contact pads on the top side of the leadframe. The leadframe has solder contact structures connected to the leadframe portions. The solder contact structures are arranged in the region of housing corners formed at the mounting surface, and are accessible at the mounting surface and/or the outer walls, or are exposed at the mounting surface and/or the outer walls. Portions of the solder contact structures which are accessible at the mounting surface and/or at the outer walls of the housing form first solder contact surfaces.

The electronic component is based on the concept that the solder contact structures are arranged in the region of the housing corners. As a result, the solder contact structures are accessible not only at the mounting surface but also at the outer walls of the housing. In the case of previously known electronic components, in contrast, the solder contact structures are arranged in the region of main axes of the housing, typically in a central region of the mounting surface of the housing.

The arrangement of the solder contact structures in the region of the housing corners advantageously promotes correct positioning and/or alignment of the housing or electronic component in the course of mounting on a carrier, during which the electronic component is soldered to electrical contact pads of the carrier. The correct positioning and alignment of the electronic component, which are substantially determined by the arrangement of the electrical contact pads of the carrier, are made possible by the fact that controlled floating of the electronic component into position in relation to the contact pads of the carrier can take place.

“Floating into position” is intended to denote a process in which an electronic component is moved and/or rotated into a position that is advantageous in terms of energy by forces acting at interfaces between the solder contact structures and a solder material arranged between the electrical contact pads of the carrier and the mounting surface of the housing of the electronic component, the solder contact structures and an environment, and the solder material and the environment. Where appropriate, interface forces at interfaces between the solder material and the contact pads of the carrier or the carrier and between the environment and the contact pads of the carrier or the carrier itself must be taken into account. In combination with at least two soldering points, a translational force and/or a torque, which position and/or align the housing in accordance with the arrangement of the contact pads of the carrier, are/is effective as a result.

Here, the electronic component floats into position in such a way that the respective solder contact structures arranged in the region of the housing corners are arranged and/or aligned in accordance with the electrical contact pads of the carrier. By virtue of the fact that the solder contact structures are formed in the region of the housing corners, these have the maximum possible spacings with respect to one another, and therefore the forces that act during the process of floating into position are particularly pronounced on account of a lever effect. Positioning of the electronic component on the carrier can thereby be made significantly easier since the requirements as regards precision required for this purpose can be reduced by virtue of the advantageous floating of the electronic component into position.

It should be noted that the arrangement of the solder contact structures in the region of the housing corners of the electronic component entails mechanical stresses in the electronic component since two materials with different coefficients of thermal expansion are in direct contact with one another in the region of the solder contact structures, namely that of the leadframe and of the moldable material, for which reason arrangement of the solder contact structures in the region of the housing corners was disregarded in previously known electronic components. However, if the size of the housing and thus also the solder contact structures is reduced, the stresses at the housing corners also diminish and can assume a technically acceptable level. It is precisely the arrangement of the solder contact structures in the region of the housing corners that advantageously makes it possible to significantly reduce the size of the solder contact structures in comparison with previously known electronic components, e.g. by up to 50%, although not restricted thereto.

Moreover, a footprint of the electronic component can be particularly small if, for example, the chip contact pads provided are arranged only toward an outer wall, as a result of which, for example, wiring of an electronic semiconductor chip to the chip contact pads takes up less space. The advantageous arrangement of the chip contact pads thereby also makes it possible to use larger electronic semiconductor chips for the electronic component.

Another common requirement on electronic components (e.g. in the automotive sector) is the possibility of inspecting the soldering points. The arrangement of the solder contact surfaces in the region of the housing corners represents a position of maximum exposure for the solder contact surfaces, thus making the soldering points particularly easy to inspect.

In one embodiment, the leadframe has a solder contact corner in the region of each of the housing corners. In other words, the solder contact structures have the solder contact corners or are configured as such. A solder contact corner is of pointed configuration and is therefore capable of breaking a surface tension of a liquid solder material. This can advantageously promote wetting of the solder contact surfaces of the leadframe or of the solder contact structures. Leadframes are typically manufactured from copper. If the leadframe does not have any other metallic coating, this may be a disadvantage for the wetting of the solder contact surfaces with the solder material. The solder contact corner enables effective wetting of solder contact surfaces which contain copper, for example, even if these are not metallized. The solder contact corner can also be referred to as a first solder control structure.

In one embodiment, the leadframe has a recess in the region of each of the housing corners. In the region of the recesses, the solder contact structures have accessible second solder contact surfaces. The recesses can also be referred to as second solder control structures. The recesses advantageously make it possible for solder material to be arranged substantially in the region of the recesses during the mounting of the electronic component. The second solder contact surfaces are produced by the formation of the recesses.

In one embodiment, the recesses extend completely through the leadframe from the top side of the leadframe to the bottom side of the leadframe. When a plurality of electronic components is separated in the course of a production process, no burr extending beyond an overall area of the electronic component is formed on the leadframe in the region of any of the recesses, and this can facilitate handling of the electronic component.

In one embodiment, the leadframe has accessible third solder contact surfaces on its top side and in the region of the housing corners. Thus, the top side of the leadframe is not covered by moldable material in the region of the third solder contact surfaces. This can be achieved, during the arrangement of the moldable material, by pressing a molding tool against the leadframe in the region of the third solder contact surfaces to be produced. During this process, the top side of the leadframe is sealed against the molding tool. As a result, it is not necessary to arrange a protective film on the bottom side of the leadframe during the embedding of the leadframe in the moldable material, even if the leadframe has recesses in the region of the housing corners extending completely through the leadframe in the vertical direction.

In one embodiment, the second solder contact surfaces and/or the third solder contact surfaces are metallized. In this case, therefore, a coating is arranged on the second solder contact surfaces. The coating comprises a metallic material. The metallized second and/or third solder contact surfaces advantageously make it possible to additionally improve the wetting properties of the solder material in the region of the recesses. It may thereby be possible for the solder material to be arranged exclusively in the region of the recesses and to come into direct contact only with the second solder contact surfaces but not with the first solder contact surfaces. The third solder contact surfaces can optionally also be wetted. Overall, metallized second and/or third solder control structures allow even more controlled and reliable floating of the electronic components into position.

In one embodiment, the solder contact structures are arranged symmetrically. The process of floating into position during the mounting of the electronic component can advantageously be additionally improved by the symmetry of the solder contact structures, such that controlled and reliable floating into position can take place.

In one embodiment, a further portion of the bottom side of the leadframe, which portion is accessible at the mounting surface and is remote from the housing corners, forms a further solder contact surface. The further solder contact surface can be arranged, for example, in the region of a center of gravity of the electronic component or, for example, in the region of a central point of the mounting surface of the housing.

The further solder contact surface can advantageously serve to dissipate heat generated during the operation of the electronic component. The solder contact structures and the further solder contact surface can also be arranged jointly in such a way that there is symmetry. For example, the further solder contact structure can be arranged in the region of a point of symmetry.

Overall, smaller solder contact structures and their advantageous position also enable better insulation/encapsulation of the same from an active region of the electronic component. In one embodiment, a respective depression is formed on the top side of the leadframe and in the region of the solder contact structures. The moldable material engages in the depressions. This advantageously reduces a risk that the moldable material will be detached from the leadframe. The greater impermeability of the electronic component with respect to liquids also reduces the risk that a flux and/or solder material will leak in during the soldering of the electronic component or even the leakage of liquid moldable material during processing. A more impermeable electronic component is robust and, in particular, corrosion-resistant.

In one embodiment, the depressions are each configured as trenches running between two adjacent outer walls of the housing. Any delamination of the moldable material from the leadframe, starting from a housing corner, which may occur under certain circumstances in the region of the trench, can advantageously be stopped. The impermeability of the electronic component is thereby increased.

In one embodiment, the leadframe has an undercut extending in the direction of the top side of the leadframe on its bottom side and on each of the sides of the solder contact structures facing away from the housing corners. The moldable material engages in the undercut. This advantageously improves the robustness and impermeability of the electronic component because delamination of the moldable material from the leadframe can be prevented.

A method for mounting an electronic component according to any one of the embodiments comprises the following method steps. A carrier having electrical contact pads arranged on a top side of the carrier is provided. A solder material is arranged on the electrical contact pads of the carrier. The electronic component is arranged on the solder material, wherein the mounting surface of the electronic component faces the carrier in such a way that the solder contact structures of the electronic component face the electrical contact pads arranged on the top side of the carrier and are arranged on the solder material, as a result of which the solder material wets the leadframe in the region of the solder contact structures. The first solder contact surfaces and/or the second solder contact surfaces and/or the third solder contact surfaces are wetted by the solder material. If the second solder contact surfaces and/or the third solder contact surfaces are metallized, the metallized second and/or third solder contact surfaces are wetted.

### BRIEF DESCRIPTION OF THE DRAWINGS

The above-described properties, features and advantages of this invention and the manner in which these are achieved are explained more clearly and in a more clearly understandable way in conjunction with the following description of the exemplary embodiments, which are explained in greater detail in conjunction with the drawings. In the drawings:

FIG. 1: shows an electronic component according to one embodiment in a perspective view;

FIG. 2: shows the electronic component of FIG. 1 in a transparent perspective view;

FIG. 3: shows a detail of the electronic component according to FIGS. 1 and 2 in the region of a housing corner in a perspective view;

FIG. 4: shows a detail of an electronic component according to an alternative embodiment in the region of a housing corner in a perspective view;

FIG. 5: shows a detail of an electronic component according to a further alternative embodiment in the region of a housing corner in a perspective view;

FIG. 6: shows the electronic component according to FIGS. 1 to 3 in another perspective view;

FIG. 7: shows an electronic component according to another embodiment in a plan view, and part of the electronic component of the further embodiment in a perspective view;

FIG. 8: shows the state of an assembly of a plurality of electronic components in the course of a production process in a plan view of a leadframe plane;

FIG. 9: shows the state of an assembly of a plurality of electronic components according to FIG. 4 in the course of the production process in a plan view of the leadframe plane; and

FIG. 10: shows a state in the course of a method for mounting an electronic component according to one of the embodiments in a perspective view.

### DETAILED DESCRIPTION OF ILLUSTRATIVE EMBODIMENTS

FIG. 1 shows schematically an electronic component 1 according to one illustrative embodiment in a perspective view.

The electronic component 1 has a housing 2. By way of example, the housing 2 has a rectangular footprint. However, the housing 2 can also have some other footprint, e.g. a square footprint. The housing 2 can have a width of, for example, 1.4 mm, a length of, for example, 2.3 mm and a height of, for example, 0.6 mm or, for example, 0.55 mm. All values should be understood to be merely illustrative and not restrictive.

The housing 2 comprises a moldable material 3 and a leadframe 4. The leadframe 4 is embedded in the moldable material 3. By way of example, the moldable material 3 comprises a silicone. However, the moldable material 3 may also comprise some other material. Alternatively, the moldable material 3 may comprise an epoxy resin, for example. By way of example, the leadframe 4 comprises copper. However, the leadframe 4 may also comprise some other metallic material. In addition, the leadframe 4 has a metallic coating, but this is not absolutely essential. By way of example, the metallic coating comprises an alloy of the metals nickel, palladium and gold (NiPdAu). The metallic coating may also comprise other metals and alloys. The leadframe 4 forms the load-bearing structure of the electronic component 1. The leadframe 4 may be embedded in the moldable material 3 using a molding process, for example.

The electronic component 1 furthermore has an electronic semiconductor chip 5. However, the electronic component 1 may also have any number of electronic semiconductor chips 5. By way of example, the electronic semiconductor chip 5 is configured as an optoelectronic semiconductor chip 5. The optoelectronic semiconductor chip 5 can be configured as a sapphire chip, for example. In this case, the electronic component 1 can also be referred to as an optoelectronic component 1.

The optoelectronic semiconductor chip 5 can be configured as a light emitting diode or as a laser diode, for example. However, the optoelectronic semiconductor chip 5 does not necessarily have to be configured to emit electromagnetic radiation. As an alternative, the optoelectronic semiconductor chip 5 may also be configured to detect electromagnetic radiation. In this case, the optoelectronic semiconductor chip 5 can be configured as a photodiode, for example. The optoelectronic component 1 can be configured, for example, as a LIDAR device, e.g. as a LIDAR device on a motor vehicle. However, the optoelectronic component 1 can also be configured as a device for measuring vital functions of persons, e.g. as a pulse oximeter.

However, the electronic semiconductor chip 5 does not have to be configured as an optoelectronic semiconductor chip 5. The electronic semiconductor chip 5 can be configured, for example, as a transistor element or as some other electronic or electrical element. However, the electronic semiconductor chip 5 may also be omitted.

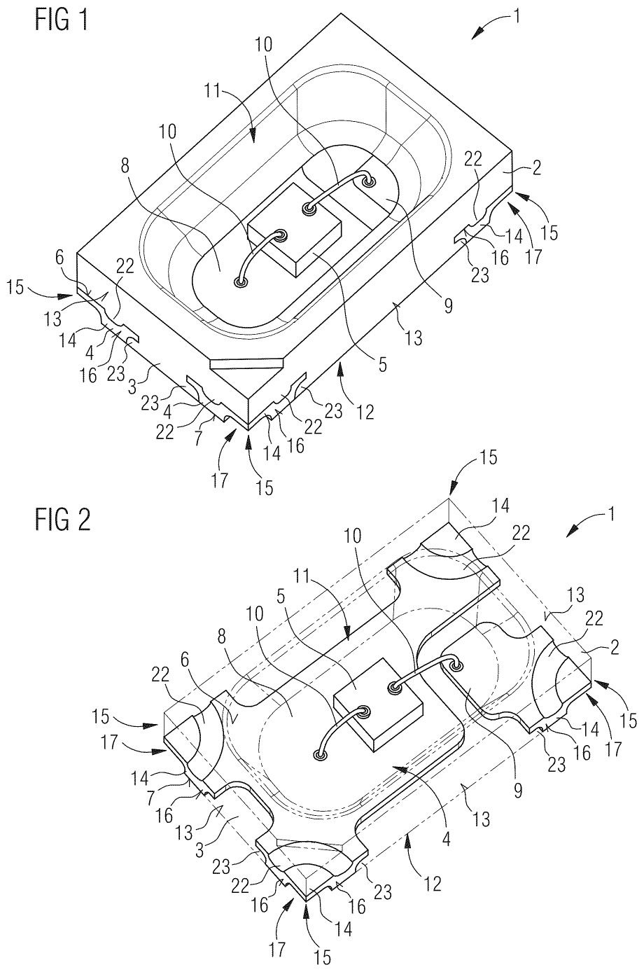

FIG. 2 schematically shows the electronic component 1 according to FIG. 1 in a perspective view, but the moldable material 3 is illustrated as transparent in order to show the leadframe 4. The reference signs in FIG. 1 are retained in the following description.

The leadframe 4 has a top side 6 and a bottom side 7 opposite the top side 6. The leadframe 4 is of planar configuration. In one embodiment, the leadframe 4 has a thickness of at least 200 μm. This provides a particularly rigid leadframe 4 which exhibits little bending, e.g. thermally induced bending. However, the thickness of the leadframe 4 is not restricted to the indicated value range. The leadframe 4 can also have additional transverse webs, which connect the leadframe portions 8, 9 to the solder contact structures 14 or interconnect solder contact structures 14.

The leadframe 4 furthermore has at least two separate leadframe portions 8, 9. The leadframe portions 8, 9 form chip contact pads on the top side 6 of the leadframe 4. The chip contact pads are provided for electrically connecting the at least one electronic semiconductor chip 5. By way of example, the electronic semiconductor chip 5 is arranged on a first leadframe portion 8 and is electrically connected to the first leadframe portion 8. In this case, the electronic semiconductor chip 5 is connected to the first leadframe portion 8 using a bonding wire 10. In addition, the electronic semiconductor chip 5 is connected to the second leadframe portion 9 using a bonding wire 10.

However, the electrical connection to the first leadframe portion 8 does not necessarily have to be made using a bonding wire 10 since the electronic semiconductor chip 5 may also alternatively have an electrical contact on a bottom side facing the first leadframe portion 8. It is also possible for both bonding wires 10 to be omitted. In addition to the electrical contact for connection to the first leadframe portion 8, it is also possible, for example, for an electronic semiconductor chip 5 arranged above the leadframe portions 8, 9 to have an electrical through-plating for connection to the second leadframe portion 9.

By way of example, the electronic component 1 according to the embodiment in FIG. 2 has a cavity 11 formed in the moldable material 3. The leadframe 4 forms a bottom of the cavity 11. The electronic semiconductor chip 5 is arranged in the cavity 11. An opening surface of the cavity 11 in the region of the leadframe 4 is smaller than an opening surface of the cavity 11 in a region facing away from the bottom or leadframe 4. As a result, the cavity 11 has a reflector shape. In the illustrative embodiment in FIG. 2, an angle of a cavity inner wall relative to the leadframe plane is 20°. However, the cavity 11 may also have some other shape.

If the electronic component 1 has a plurality of electronic semiconductor chips 5, the electronic semiconductor chips 5 can be arranged jointly in one cavity 11. However, it is also possible for a separate cavity 11 to be provided for each electronic semiconductor chip 5. However, it is not absolutely essential to provide a cavity 11. Alternatively, the electronic semiconductor chip 5 can also be embedded in the moldable material 3.

Alternatively, the cavity 11 can be filled with potting material. In addition to mechanical protection of the electronic semiconductor chip 5, the potting material can perform various other functions; e.g. it can comprise a material that converts wavelengths designed to modify a wavelength of the emitted electromagnetic radiation. Scattering particles may also be provided in the potting material, for example.

The housing 2 of the electronic component 1 has a mounting surface 12 and outer walls 13. The mounting surface 12 is formed in the region of the bottom side 7 of the leadframe 4, i.e. on a bottom side of the housing 2. The bottom side of the housing 2 or mounting surface 12 is thus arranged on an opposite side of the leadframe 4 from the chip contact pads. In the course of a soldering process, in which the electronic component 1 is to be soldered to a carrier, e.g. a printed circuit board (PCB), the electronic component 1 is arranged with the mounting surface 12 facing the carrier. For surface mounting by soldering to a carrier, the electronic component 1, to be more precise the leadframe 4, has solder contact structures 14.

The solder contact structures 14 are arranged in the region of housing corners 15 of the housing 2, which are formed on the mounting surface 12, and are accessible at the mounting surface 12 and/or the outer walls 13. The solder contact structures 14 are connected in a mechanically rigid manner to the leadframe portions 8, 9. By way of example, the first leadframe portion 8 is connected to three solder contact structures 14, while the second leadframe portion 9 is connected only to one solder contact structure 14. It is also possible for each of the leadframe portions 8, 9 to be connected to two solder contact structures 14, for example. In general, it is expedient here for each leadframe portion 8, 9 configured as a chip contact pad to be connected to at least one solder contact structure 14.

In the region of the solder contact structures 14, a solder material can be arranged in order to produce electrical contacting of the electronic semiconductor chip 5 to electrical contact pads of a carrier via the leadframe portions 8, 9. On account of the rectangular footprint or mounting surface 12 of the housing 2, the leadframe 4 has a total of four solder contact structures 14. The housing 2 can also have a different number of housing corners 15. In corresponding fashion, the leadframe 4 can also have a different number of solder contact structures 14. One solder contact structure 14 is provided for each housing corner 15. However, it is not necessary to provide a solder contact structure 14 for each housing corner 15.

By way of example, the solder contact structures 14 of the electronic component 1 in FIG. 2 are accessible or exposed both at the mounting surface 12 and at the outer walls 13 of the housing 2. However, it may also be the case that the solder contact structures 14 are accessible and exposed only at the mounting surface 12 or only at the outer walls 13. It is also not necessary for the solder contact structures 14 to be accessible at all the outer walls 13 and/or housing corners 15 of the housing 2, as shown by way of example in FIG. 2; as an alternative, they may be exposed only in one part of the outer walls 13 and/or housing corners 15 of the housing.

The solder contact structures 14 are each arranged directly in the region of the housing corners 15. The solder contact structures 14 thus form the housing corners 15 of the housing 2 in the region of the mounting surface 12. Alternatively, the solder contact structures 14 can each be arranged only in an area surrounding the housing corners 15 and are not directly in the region of the housing corners 15. This is the case, for example, when the solder contact structures 14 are accessible only at the mounting surface 12. However, the solder contact structures 14 must be arranged at least in a region of the housing corners 15 and not, for instance, in a central region of the housing 2 or, for instance, along central axes of the housing 2, i.e. not in a region of the housing 2 remote from the housing corners 15, for instance.

By virtue of the arrangement of the solder contact structures 14 in the region of the housing corners 15 and by virtue of their accessibility at the mounting surface 12 and/or the outer walls 13, the electronic component is configured as a quad flat no leads component (QFN). A typical, though not necessary, feature of QFN components is that their solder contact structures 14 do not protrude from the housing 2.

The arrangement of the solder contact structures 14 in the region of the housing corners 15 enables correct positioning and/or alignment of the electronic component 1 in the course of solder mounting on a carrier. This is made possible by the fact that controlled floating of the electronic component 1 into position in relation to an arrangement of electrical contact pads of the carrier can take place.

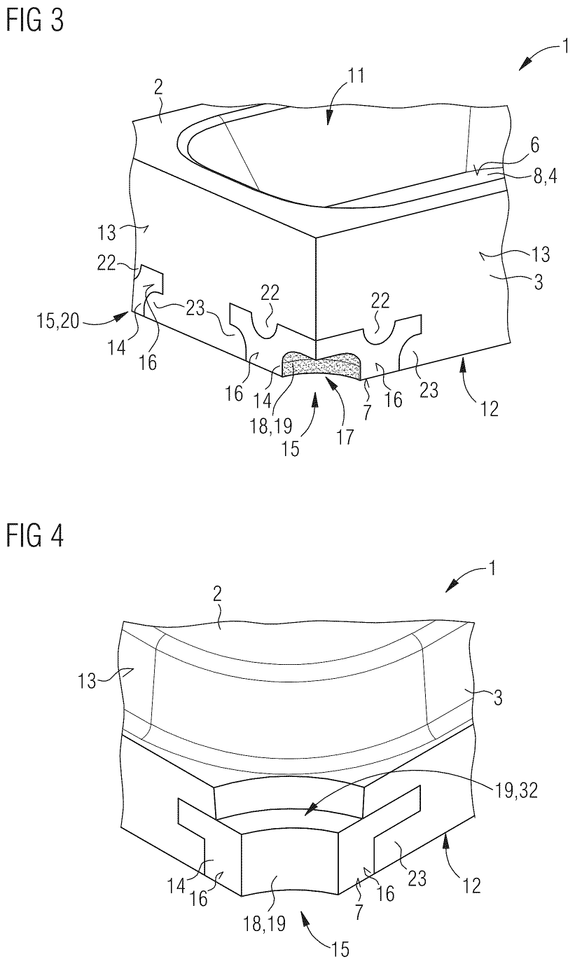

FIG. 3 shows schematically a detail of the electronic component 1 according to FIGS. 1 and 2 in the region of a housing corner 15 in a perspective view. The reference signs in FIGS. 1 and 2 are retained in the following description. For the sake of simplicity, FIG. 3 does not show an electronic semiconductor chip 5, which can in any case also be omitted in the case of the electronic components 1.

The solder contact structures 14 have first solder contact surfaces 16. The first solder contact surfaces 16 form those portions of the solder contact structures 14 which are exposed at the mounting surface 12 and/or at the outer walls 13 of the housing 2. First solder contact surfaces 16 which are exposed at the mounting surface 13 are formed by portions of the bottom side 7 of the leadframe 4. First solder contact surfaces 16 which are exposed at the outer walls 13 are formed by edge walls of the leadframe 4. The first solder contact surfaces 16 are of flat configuration. In the region of the housing corners 15, the solder contact structures 14 each have a recess 17. By virtue of the provision of the recesses 17, the solder contact structures 14 also have second solder contact surfaces 18 in addition to the first solder contact surfaces 16. By virtue of the fact that the second solder contact surfaces 18 are produced by the provision of the recesses 17, the second solder contact surfaces 18 have second solder contact surfaces 18 formed in accordance with a geometry of the recesses 17.

A solder material can wet the first and/or the second solder contact surfaces 16, 18. In the embodiment in FIG. 3, the recesses 17 are provided as solder control structures. They serve to receive a solder material. In this case, it is possible for the solder material to be arranged within the recesses 17 in such a way that it wets only the second solder contact surfaces 18. In order to improve the wetting properties of the second solder contact surfaces 18, a metallic coating 19 is arranged on each of the second solder contact surfaces 18. By way of example, the metallic coating 19 comprises gold, but it may also comprise some other metallic material, e.g. an alloy. However, the metallic coating 19 may also be omitted.

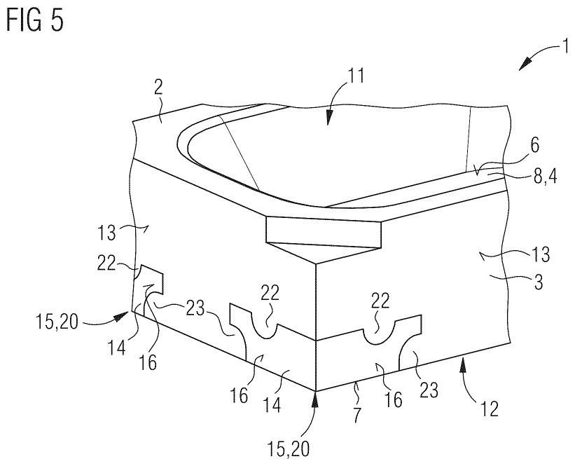

Purely by way of example, FIG. 3 shows that the second solder contact surfaces 18 have a curved spherical shape. However, the second solder contact surfaces 18 may also be configured differently. FIG. 4 shows schematically a detail of an electronic component 1 according to an alternative embodiment in the region of a housing corner 15 in a perspective view. The electronic components 1 in FIGS. 3 and 4 have similarities. Similar or identical elements are provided with the same reference signs in FIGS. 3 and 4. In the text which follows, only the differences between the electronic component 1 in FIG. 4 and the electronic component 1 in FIG. 3 are explained. For the sake of simplicity, no electronic semiconductor chip 5 is shown in FIG. 4.

In contrast to the electronic component 1 according to FIG. 3, the electronic component according to FIG. 4 has recesses 17 which extend completely through the leadframe 4 from the top side 6 of the leadframe 4 to the bottom side 7 of the leadframe 4. By way of example, the second solder contact surfaces 18 are in the form of segments of a lateral surface of a cylinder. In this embodiment, however, it is important that the recesses 17 and the second solder contact surfaces 18 extend from the bottom side 7 to the top side 6 of the leadframe 4. In other words, the second solder contact surfaces 18 each have common edges with the top side 6 and the bottom side 7 of the leadframe 4.

Moreover, the leadframe 4 of the electronic component 1 in FIG. 4 has accessible third solder contact surfaces 32 on its top side 6 and in the region of the housing corners 15. In this case too, the second solder contact surfaces 18 and/or the third solder contact surfaces 32 can be metallized, wherein FIG. 4 shows by way of example that both the second and the third solder contact surfaces 18, 32 are metallized. The optionally metallized third solder contact surfaces 32, like the first solder contact surfaces 16 and the optionally metallized second solder contact surfaces 18, enable wetting with a solder material.

The third solder contact surfaces 32 can be produced by pressing a molding tool against the top side 6 of the leadframe 4 in the region of the third solder contact surfaces 32 to be produced while the leadframe 4 is being embedded in the moldable material 3.

FIG. 5 shows schematically a detail of an electronic component 1 according to a further alternative embodiment in the region of a housing corner 15 in a perspective view. The electronic components 1 in FIGS. 3 and 4 have similarities. Similar or identical elements are provided with the same reference signs in FIGS. 3 and 4. In the text which follows, only the differences between the electronic component 1 in FIG. 5 and the electronic component 1 in FIG. 3 are explained. For the sake of simplicity, no electronic semiconductor chip 5 is shown in FIG. 5 either.

In contrast to the electronic component 1 according to FIG. 3, the electronic component according to FIG. 5 does not have any recesses 17 in the region of the housing corners 15. Instead, the leadframe 4 has a solder contact corner 20 in the region of each of the housing corners 15. In this case, the second solder contact surfaces 18 are omitted. The solder contact corner 20 is provided for the purpose of breaking a surface tension of a solder material. It is thereby possible to promote wetting of the first solder contact surfaces 16.

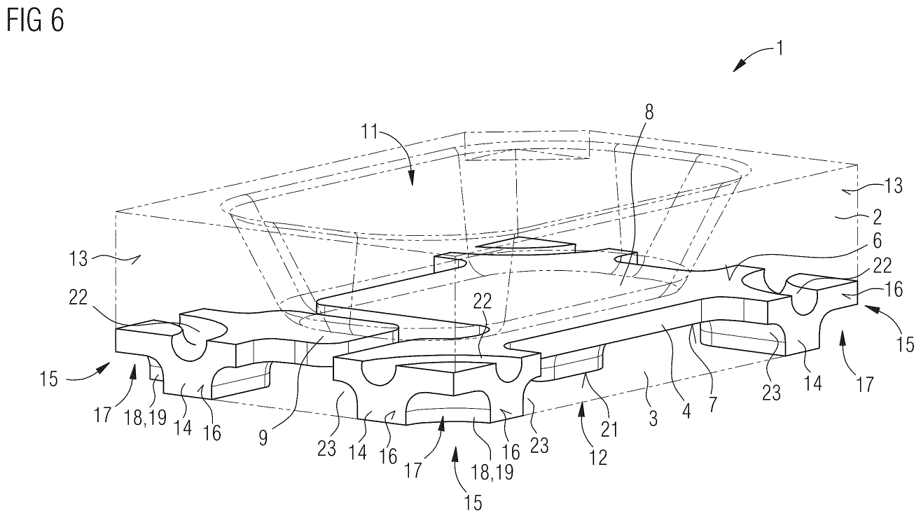

FIG. 6 schematically shows the entire electronic component 1 according to FIGS. 1 to 3 in a further perspective view, wherein the moldable material 3 is once again illustrated as transparent, and no electronic semiconductor chip 5 is shown. The reference signs previously used are retained in the following description.

The solder contact structures 14 are arranged symmetrically. As a result, the first and optionally the second solder contact surfaces 16, 18 are also arranged symmetrically. In the illustrative embodiment, there is symmetry of the solder contact structures 14 with respect to the main axes and symmetry with respect to a central point of the housing 2. These symmetries can also be interpreted as rotational symmetries with respect to rotation around the central point. In the case of a square mounting surface 12 or footprint of the housing 2, a degree of symmetry is additionally increased. The symmetrical arrangement of the solder contact structures 14 in combination with their arrangement in the region of the housing corners 15 enables excellent floating into position of the housing 2 since in this way the forces acting at the relevant interfaces can act symmetrically on the housing 2. However, symmetrical arrangement of the solder contact structures 14 is not necessarily required.

In the case of the electronic component 1 in FIG. 6, a further portion of the bottom side 7 of the leadframe 4 is exposed at the mounting surface 12 and forms a further solder contact surface 21. Thus, in contrast to the solder structures 14, the further solder contact surface 21 is not arranged in the region of the housing corners 15 but remote from these, e.g. being arranged in a central region of the housing 2, as shown in FIG. 6. The further solder contact surface 21 can be arranged in the region of a point of symmetry and/or symmetrically with respect to the main axes of the housing. It is also possible to provide a plurality of further solder contact surfaces 21, which are each remote from the housing corners 15 and are exposed or accessible at the mounting surface 12. The further solder contact surface 15 or optionally a plurality of further solder contact surfaces 21 may also be omitted.

In order to prevent delamination of the moldable material 3 from the leadframe 4, a respective trench 22 running between two adjacent outer walls 13 of the housing 2 is formed on the top side 6 of the leadframe 4 and in the regions of the solder contact structures 14. Here, the trench 22 extends as far as the outer walls 13 of the housing 2 and ends at the outer walls 13. The moldable material 3 embeds the leadframe 4 and engages in the trench 22. It is thereby possible for delamination of the moldable material 3 from the leadframe 4 that is beginning at the housing corners 15 to be stopped in the region of the trenches 22 and to prevent further delamination.

In a plane perpendicular to the leadframe 4 or to the top side 6 of the leadframe 4, i.e. perpendicularly to the leadframe plane, the trenches 22 each have a U-shaped cross-sectional profile. However, the trenches may also have a V-shaped or rectangular cross-sectional profile or some other cross-sectional profile. By way of example, the trenches 22 each extend along portions of toruses in the leadframe plane, i.e. parallel to the top side 6 of the leadframe 4. Owing to the rectangular footprint of the housing 2, the toruses along which the trenches 22 extend are each quarter-toruses.

However, it is not necessary to provide trenches 22 which each extend between two outer walls 13 and reach as far as the outer walls 13 in order to prevent delamination of the moldable material 3 from the leadframe 4. Instead of trenches 22 it is also possible to arrange depressions of a different configuration, which do not extend as far as the outer walls 13, on the top side 6 of the leadframe 4 and in each case in the region of the solder contact structures 14. However, the trenches 22 offer the advantage that, in addition to the aspect of better bonding of the moldable material 3 to the leadframe 4, they also improve impermeability of the electronic component 1 since a probability of ingress of liquids in the region of the housing corners 15 or of the solder contact structures 14 is reduced by the presence of the trenches 22 extending right up to the outer walls 13 since a sealing effect up to the outer walls 13 is provided. In the other regions too, the electronic component 1 is of course sealed off by interlocking engagement between the leadframe 4 and the moldable material 3. However, the depressions and, in particular, the trenches 22 offer an additional improvement of the impermeability at the housing corners 15.

For an additional improvement in the bonding of the moldable material 3 to the leadframe 4 and impermeability of the electronic component 1, the leadframe 4 has an undercut 23 extending in the direction of the top side 6 of the leadframe 4 on its bottom side 7 and on each of the sides of the solder contact structures 14 which face away from the housing corners 15. Thus, the undercuts 23 are each formed on opposite sides of the solder contact structures from the recesses 17 or the solder contact corners 20. The moldable material 3 engages in the undercut 23.

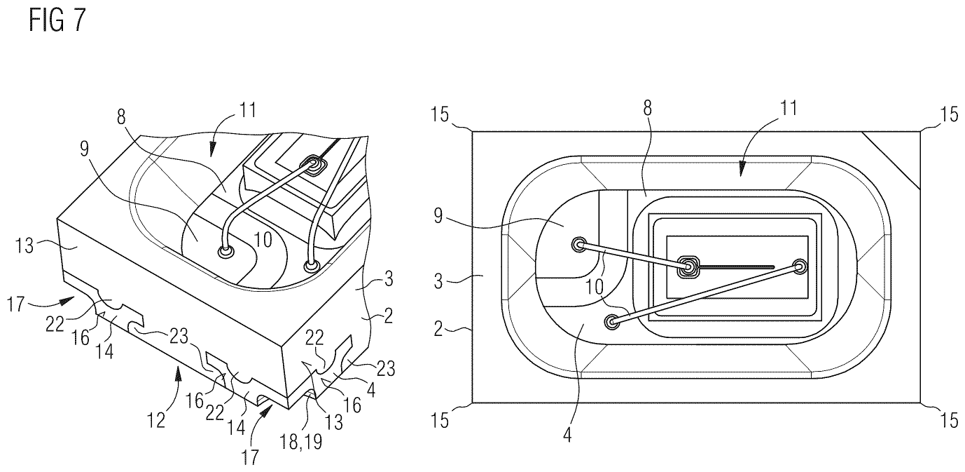

The arrangement of the solder contact structures 14 in the region of the housing corners 15 not only enables the impermeability of the electronic component 1 to be improved in a simple manner but also makes it possible to provide an electronic component 1 that has a smaller footprint or mounting surface 12 and/or optionally a larger semiconductor chip 5. This is explained with reference to FIG. 7. FIG. 7 shows an electronic component 1 according to another embodiment in a plan view, and part of the electronic component 1 of the further embodiment in a perspective view. The electronic components 1 in FIG. 7 have similarities to the electronic component 1 in FIGS. 1 to 5. Similar or identical elements are provided with the same reference signs in FIG. 7. In the text which follows, only the differences between the electronic component 1 in FIG. 7 and the electronic components 1 in FIGS. 1 to 6 are explained.

In contrast, for instance, to the embodiment in FIG. 1, in which contacting of the electronic semiconductor chip 5 takes place on both sides, there is one-sided contacting in the embodiment of the electronic component 1 in FIG. 7. One-sided contacting should be understood to mean that the electronic semiconductor chip 5 is electrically contacted with the first leadframe portion 8 and the second leadframe portion 9 in such a way that both bonding wires 10 project from the electronic semiconductor chip 5 in the direction of a common outer wall 13. In the case of the two-sided contacting according to FIG. 1, the bonding wires 10 project from the electronic semiconductor chip 5 in the direction of opposite outer walls 13 of the housing 2. One-sided electrical contacting is made possible by the fact that the solder contact structures 14 are arranged in the region of the housing corners 15, and the leadframe 4 has at least two separate leadframe portions 8, 9, wherein each leadframe portion 8, 9 is connected to at least one solder contact structure 14. As a result, when viewed from the electronic semiconductor chip 5, both chip contact pads are formed between the electrical semiconductor chip 5 and a common outer wall 13. This makes it possible to arrange at least part of the first and the second leadframe portion 8, 9 in the region of a common outer wall 13 of the housing 2. In this way, it is possible to provide an electronic component 1, the mounting surface 12 of which can be reduced in comparison with the variant in FIG. 1 since less space is required for the bonding wires 10. As an alternative or in addition, a larger electronic semiconductor chip 5 can be used if a space saving is associated with the one-sided contacting of the electronic semiconductor chip 5.

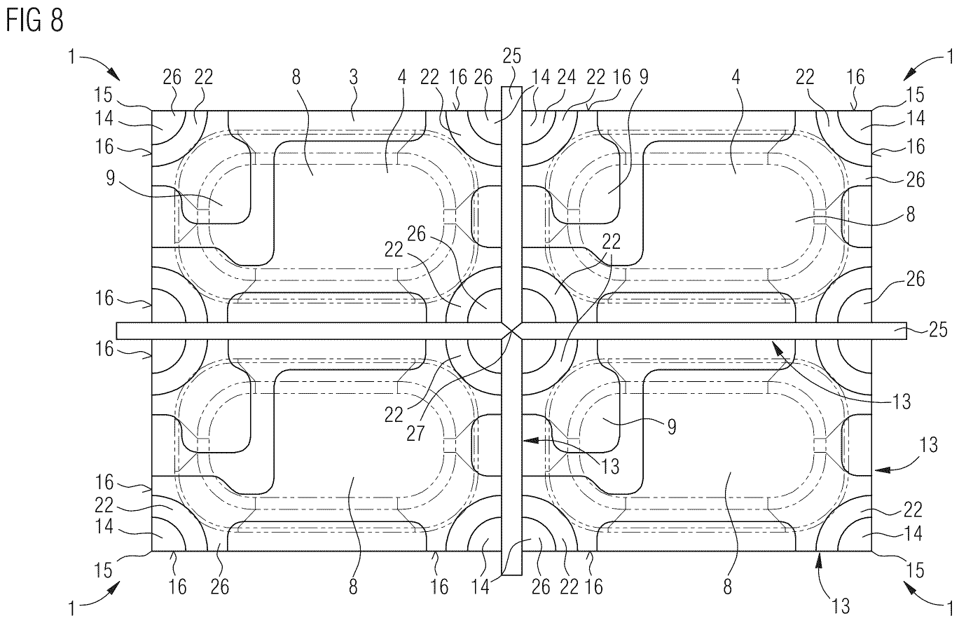

FIG. 8 shows schematically the state of an assembly of a plurality of electronic components 1 in the course of a production process in a plan view of the leadframe plane with a moldable material 3 illustrated as transparent. The optoelectronic components 1 can be configured in accordance with one of the embodiments in FIGS. 1 to 7 which have been explained. The reference signs previously used are retained in the following description.

The leadframe 4 of the electronic components 1 are initially in the form of a leadframe assembly 24. The leadframe assembly 24 was embedded in the moldable material 3 in the state shown in FIG. 8. FIG. 8 thus shows a state immediately before the finishing of the electronic components 1. Any number of electronic components 1 can be produced simultaneously. Purely by way of example, an assembly of in total four electronic components 1 that are to be produced is shown. During production, separation into separate electronic components 1 takes place along separation planes 25 illustrated in FIG. 8, e.g. using a sawing process. Separation along the separation planes 25 results in the formation of the outer walls 13 of the housings 2 of the electronic components 1. Owing to the illustrative rectangular footprint of the housing 2, the separation planes 25 are arranged so as to run perpendicularly to one another.

In accordance with the illustrative number of electronic components 1 to be produced, the leadframe assembly 24 has a total of four first leadframe portions 8 and four second leadframe portions 9. There is one first and one second leadframe portion 8, 9 arranged in the region of each electronic component 1 to be produced. The first and the second leadframe portions 8, 9 are each arranged in a rectangular configuration. Moreover, the leadframe assembly 24 has solder structure portions 26, which are arranged in a rectangular configuration. The solder structure portions 26 are each arranged at points of intersection of the separation planes 25. As a result, each of 4 adjacent electronic components 1 to be produced shares a solder structure portion 26. The leadframe portions 8, 9 are each arranged in the region between the separation planes 25. In this case, the arrangements of the first and second leadframe portions 8, 9 are offset laterally with respect to one another.

Each solder structure portion 26 is rigidly connected to precisely one leadframe portion 8, 9 of a respective electronic component 1 comprising the relevant solder structure portion 26. In this case, each solder structure portion 26 is rigidly connected to a total of three first leadframe portions 8 and to just one second leadframe portion 9. Each first leadframe portion 8 is rigidly connected to a total of three solder structure portions 26, which it shares with adjacent electronic components 1. The solder contact structures 14 are provided in the region of the solder structure portions 26. As a result, a solder structure portion 26 comprises the solder contact structures 14 of four adjacent leadframes 4 or electronic components 1 in the leadframe assembly 24. The first leadframe portions 8 are thus each connected to three solder contact structures 14. Each second leadframe portion 9 is rigidly connected to just one solder structure portion 26 and, as a result, to just one solder contact structure 14. In particular, the second leadframe portions 9 are not connected to first leadframe portions 8 in order to be able to form the separate chip contact pads.

The solder structure portions 26 also comprise the trenches 22 and/or undercuts 23 of in each case four adjacent leadframes 4 or electronic components 1 in the leadframe assembly 24. In the leadframe assembly 24, it is appropriate that the trenches 22 and/or undercuts 23 of the four adjacent solder contact structures 14 should initially be formed in such a way as to be interconnected. The interconnected trenches 22 and/or undercuts 23 are each arranged around a central point 27 of the solder structure portions 26. The mutually perpendicular separation planes 25 are chosen in such a way that they intersect at the central points 27 of the solder structure portions 26. In this way, solder contact structures 14 that are adjacent to one another in the leadframe assembly 24 and are rigidly connected to one another are separated from one another. At the same time, the interconnected trenches 22 and/or undercuts 23 are separated from one another in such a way that they are each arranged in the region of the housing corners 15 produced by the separation process.

The solder structure portions 26 furthermore have the optionally provided recesses 17. These are arranged directly on the central point 27 of a solder structure portion 26. The recesses 17 are produced before the separation process. The second solder contact surfaces 18, 32 are optionally metallized before separation.

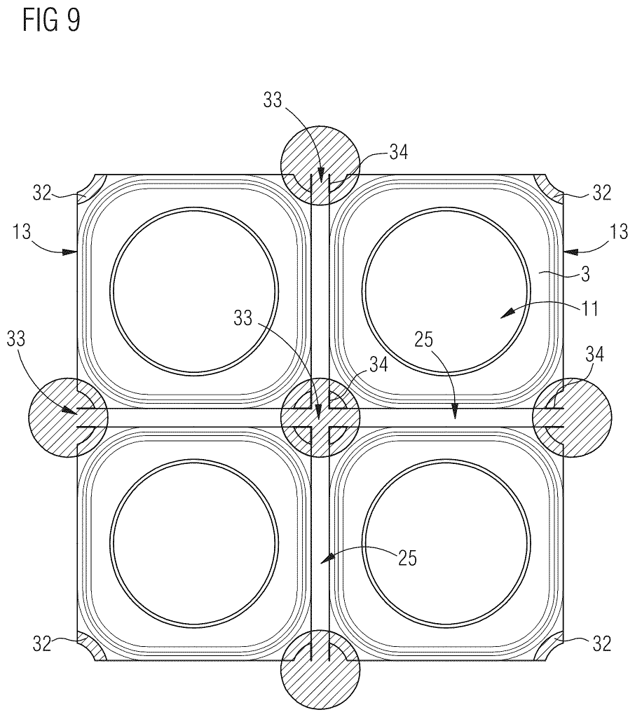

FIG. 9 shows schematically a plurality of electronic components 1 according to the embodiment in FIG. 4 after the production process in a plan view. The reference signs previously used are retained in the following description.

The recesses 17 extend completely through the leadframe 4 in the vertical direction with respect to the top side 6 of the leadframe 4, as per FIG. 4. To produce the third solder contact surfaces 32, a molding tool 33 is pressed against the top side 6 in the region of the solder structure portions 26, in the region of the cylindrical recesses 17 of the leadframe assembly 24 and in the region of the third solder contact surfaces 32 to be produced, whereby an interface between the top side 6 and the molding tool 33 is sealed in these regions as the leadframe 4 is embedded in the moldable material 3. In FIG. 9, the molding tool 33 is shown only in part. Here, only portions of an upper part of the molding tool 33 are shown, which are pressed against the top side 6 in the region of the solder structure portions 26, in the region of the cylindrical recesses 17 of the leadframe assembly 24 and in the region of the third solder contact surfaces 32 to be produced, wherein these are illustrated as transparent. The upper part of the molding tool 33 furthermore has structures for producing the cavities 11, which are not shown in FIG. 9. The molding tool 33 furthermore has a lower part, which is pressed against the bottom side of the leadframe assembly 24, which is likewise not shown in FIG. 9 for the sake of clarity. By virtue of the fact that the upper part of the molding tool 33 is pressed on in the region of the third solder contact surfaces 32 to be produced, there is no need to provide a protective film between the lower part of the molding tool 33 and the bottom side 7 to cover the recesses 17, even if these extend completely through the leadframe 4, since a sealing effect is already achieved with the aid of the molding tool 33. This ensures that no moldable material 33 can reach the bottom side 7 through the recesses 17.

By virtue of the fact that the molding tool 33 is pressed against the top side 6 and that no moldable material 3 is arranged above the third solder contact surfaces 32, a through opening in the moldable material 3 and in the region of the solder structure portions 26 is initially formed in the assembly. These can simplify the process of separation since the recesses 17 can be used as adjustment markers during the separation process. This enables separation to be carried out from the top side 6. This allows compensation of a possible offset between the molding tool 33 and the leadframe assembly 24 or the cavities 11 formed by the moldable material 3 and the leadframe 4 or the mounting surface 12. The offset is therefore made up of tolerances during the manufacture of the (etched) leadframe 4 and tolerances in respect of a lateral position during insertion of the leadframe 4 into the molding tool 33. In addition, tolerances during the separation process contribute to the offset. The offset can assume values of up to 100 μm, for example.

Tolerances during separation can occur especially if separation is carried out from the bottom side 7. Separation from the top side 6 of the leadframe 4 can make it possible to substantially eliminate the offset since a correction can be made directly in relation to the cavities 11 and the recesses 17. Compensation is performed by correcting the positions of the separating planes 25 on the basis of the offset, which can be determined by pattern recognition, for example.

In the separation process, a respective burr 34 is formed on the leadframe 4 in the region of the recesses 17 and in each case in the region of an outer wall 13 to be produced. FIG. 9 shows this scenario by way of example. Each burr 34 is formed by the sawing or milling along the separation planes 25 and projects away from the recess 17 parallel to an outer wall 13. In the illustrative embodiment with recesses 17 which extend completely through the leadframe 4 from the top side 6 of the leadframe 4 to the bottom side 7 of the leadframe 4, none of the burrs 34 projects beyond an overall area of the electronic components 1, and this can simplify the handling of the electronic components 1.

The second and/or third solder contact surfaces 18, 32 can likewise optionally be metallized before separation. Saw cuts made along the separation planes 25 can have a width of 200 μm, for example, but the width stated is merely illustrative.

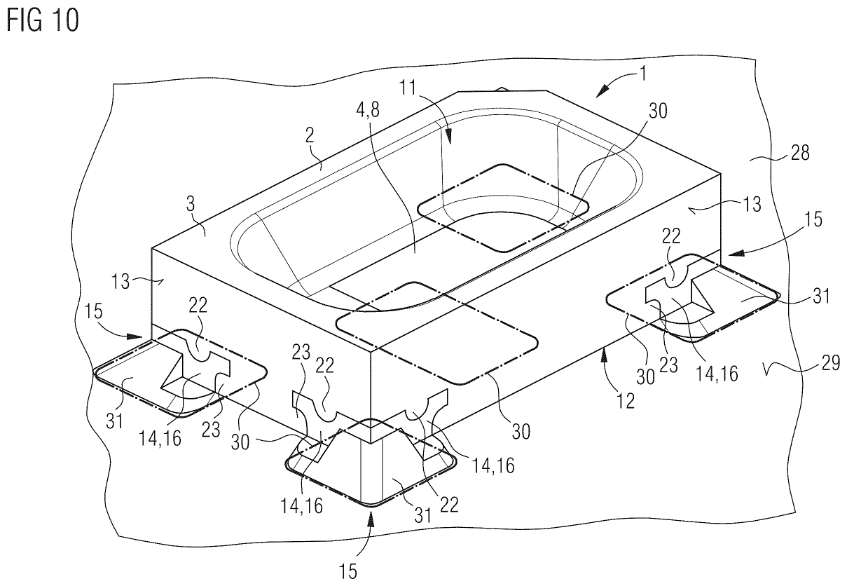

FIG. 10 shows schematically a state in the course of a method for mounting an electronic component 1 according to one of the embodiments described in a perspective view. The mounting of the electronic component 1 can also be referred to as solder mounting. The reference signs previously used are retained in the following description.

In the course of mounting the electronic component 1, the carrier 28 with electrical contact pads 30 arranged on a top side 29 of the carrier 28 is first of all supplied. The carrier 28 can be configured as a printed circuit board, for example. A solder material 31 is arranged on the electrical contact pads 30 of the carrier 28. The electronic component 1 is arranged on the solder material 31. The mounting surface 12 of the electronic component 1 faces the carrier 28 in such a way that the solder contact structures 14 of the electronic component 1 face the electrical contact pads 20 arranged on the top side 29 of the carrier 28 with the first solder contact surfaces 16 exposed at the mounting surface 1 and optionally with further solder contact surfaces 21 and are arranged on the solder material 31, as a result of which the solder material 31 wets the leadframe 4 in the region of the solder contact structures 14.

If the leadframe 4 has a solder contact corner 20 in the region of each of the housing corners 15, the first solder contact surfaces 16 are wetted by the solder material 31. If the solder contact structures 14 have a recess 17 in the region of each of the housing corners 15, the solder material 31 is arranged in the recesses 17, and the second solder contact surfaces 18 are wetted by solder material. After the curing of the solder material 31, the electronic component 1 is mounted on the carrier 28.

The invention has been illustrated and described in greater detail with reference to the preferred exemplary embodiments. However, the invention is not restricted to the examples disclosed. On the contrary, other variations can be derived therefrom by a person skilled in the art without exceeding the scope of protection of the invention.

1.-12. (canceled)

13. An electronic component comprising:
a housing with a moldable material;
a leadframe embedded in the moldable material; and
an electronic semiconductor chip,
wherein the housing has a mounting surface and outer walls,
wherein the leadframe has a top side and a bottom side situated opposite the top side,
wherein the leadframe has at least two separate leadframe portions,
wherein the leadframe portions form chip contact pads on the top side,
wherein the leadframe has solder contact structures connected to the leadframe portions,
wherein the solder contact structures are arranged in regions of housing corners formed at the mounting surface, and are accessible at the mounting surface and/or the outer walls,
wherein portions of the solder contact structures, which are accessible at the mounting surface and/or at the outer walls of the housing, form first solder contact surfaces,
wherein the electronic semiconductor chip is connected to a first leadframe portion and a second leadframe portion by a bonding wire, respectively, and
wherein the electronic semiconductor chip is electrically contacted with the first leadframe portion and the second leadframe portion such that both bonding wires project from the electronic semiconductor chip in a direction of a common outer wall.

14. The electronic component according to claim 13, wherein the leadframe has a solder contact corner in a region of each of the housing corners.

15. The electronic component according to claim 13,
wherein the leadframe has a recess in the region of each of the housing corners, and
wherein the solder contact structures have accessible second solder contact surfaces in regions of the recesses.

16. The electronic component according to claim 15, wherein the recesses extend completely through the leadframe from the top side to the bottom side.

17. The electronic component according to claim 15, wherein the second solder contact surfaces are metallized.

18. The electronic component according to claim 13, wherein the leadframe has accessible third solder contact surfaces on the top side and in the regions of the housing corners.

19. The electronic component according to claim 18, wherein the third solder contact surfaces are metallized.

20. The electronic component according to claim 13, wherein the solder contact structures are arranged symmetrically.

21. The electronic component according to claim 13, wherein a further portion of the bottom side, which portion is accessible at the mounting surface and is remote from the housing corners, forms a further solder contact surface.

22. The electronic component according to claim 13,
wherein a respective depression is formed on the top side and in regions of the solder contact structures, and
wherein the moldable material engages in the depressions.

23. The electronic component according to claim 22, wherein each of the depressions is a trench running between two adjacent outer walls of the housing.

24. The electronic component according to claim 13,
wherein the leadframe has an undercut extending in a direction of the top side on the bottom side and on each side of the solder contact structures facing away from the housing corners, and
wherein the moldable material engages in the undercut.

25. A method for mounting the electronic component according to claim 13, the method comprising:
providing a carrier having electrical contact pads arranged on a top side of the carrier;
arranging a solder material on the electrical contact pads of the carrier;
arranging the electronic component on the solder material;
wherein the mounting surface of the electronic component faces the carrier such that the solder contact structures of the electronic component face the electrical contact pads arranged on the top side of the carrier and are arranged on the solder material, as a result of which the solder material wets the leadframe in the region of the solder contact structures, and
wherein the first solder contact surfaces and/or second solder contact surfaces and/or third solder contact surfaces are wetted by the solder material.
